(19) United States
(12) Patent Application Publication
(10) Pub. No.: US 2016/0090665 A1
(43) Pub. Date: Mar. 31, 2016

(54) APPARATUS FOR PRODUCING GROUP III NITRIDE CRYSTAL, AND METHOD FOR PRODUCING THE SAME

(71) Applicant: Panasonic Intellectual Property Management Co., Ltd., Osaka (JP)

(72) Inventors: YOSHIO OKAYAMA, Osaka (JP); RYO KUWABARA, Hokkaido (JP); TOMIO YAMASHITA, Osaka (JP); YUSUKE MORI, Osaka (JP); MAMORU IMADE, Osaka (JP)

(21) Appl. No.: 14/847,188

(22) Filed: Sep. 8, 2015

(30) Foreign Application Priority Data
Sep. 25, 2014 (JP) 2014-195427
Jun. 29, 2015 (JP) 2015-130221

(51) Int. Cl. C30B 25/10; C30B 29/40; C30B 25/14; C30B 25/12; C01B 21/06; C30B 25/08

(52) U.S. Cl. CPC C30B 25/10; C01B 21/0632; C30B 25/08; C30B 25/14; C30B 25/12; C30B 29/406

(57) ABSTRACT

Apparatus and method for producing a Group III nitride crystal are to be provided. The apparatus for producing a Group III nitride crystal, contains: a chamber; a nitrogen element-containing gas supplying port for supplying a nitrogen element-containing gas to the chamber; a compound gas supplying port for supplying a compound gas of the Group III element to the chamber, so as to mix the compound gas with the nitrogen element-containing gas; a discharging port for discharging the compound gas and the nitrogen element-containing gas thus mixed, outside the chamber; a holder for holding a seed substrate at a position that is on a downstream side of a mixing point of the compound gas and the nitrogen element-containing gas and is an upstream side of the discharging port; a first heater for heating the seed substrate; and a second heater for heating a space between the mixing point and the seed substrate to a temperature that is higher than a temperature heated by the first heater.

### BACKGROUND

1. Technical Field

The present disclosure relates to an apparatus for producing a Group III nitride crystal, and a method for producing the same.

2. Description of Related Art

As an apparatus for producing a Group III nitride crystal, a production method using a Group III oxide as a raw material has been developed (see, for example, JP-A-2009-234800).

The reaction system in the production method will be described. Ga₂O₃ is heated, and hydrogen gas is introduced thereto in the heated state. The hydrogen gas thus introduced is reacted with Ga₂O₃ to form Ga₂O gas (the following reaction scheme (I)). The Ga₂O gas thus formed is reacted with ammonia gas to form a GaN crystal on a seed substrate (the following reaction scheme (II)).

Ga₂O₃+2H₂->Ga₂O+2H₂O (I)

Ga₂O+2NH₃->2GaN+H₂O+2H₂ (II)

However, there have been cases where the reaction of the scheme (II) occurs in other places than the seed substrate, and GaN crystals are deposited therein. In particular, the crystals deposited on the upstream side of the gas flow path are transported with the gas flow and attached to the seed substrate in some cases, which may cause deterioration in quality of the GaN crystal thus formed.

### SUMMARY

One of the objects of the disclosure is to provide an apparatus and a method for producing a Group III nitride crystal that are capable of growing a crystal with high quality.

For achieving the above and other objects, the disclosure relates to as one aspect thereof an apparatus for producing a Group III nitride crystal, containing:

a chamber;

a nitrogen element-containing gas supplying port for supplying a nitrogen element-containing gas to the chamber;

a compound gas supplying port for supplying a compound gas of the Group III element to the chamber, so as to mix the compound gas with the nitrogen element-containing gas;

a discharging port for discharging the compound gas and the nitrogen element-containing gas thus mixed, outside the chamber;

a holder for holding a seed substrate at a position that is on a downstream side of a mixing point of the compound gas and the nitrogen element-containing gas and is an upstream side of the discharging port;

a first heater for heating the seed substrate; and

a second heater for heating a space between the mixing point and the seed substrate to a temperature that is higher than a temperature heated by the first heater.

The disclosure also relates to as another aspect a method for producing a Group III nitride crystal, containing a step of producing a Group III nitride crystal by using the aforementioned apparatus for producing a Group III nitride crystal.

According to the apparatus and method for producing a Group III nitride crystal of the aspects of the disclosure, a crystal, with high quality may be produced.

### BRIEF DESCRIPTION OF THE DRAWINGS

FIG. 1 is a schematic cross sectional view showing a production apparatus according to an embodiment of the disclosure.

FIG. 2 is another schematic cross sectional view showing a production apparatus according to an embodiment of the disclosure.

FIG. 3 is a schematic cross sectional view showing a production apparatus according to a modified embodiment of the disclosure.

FIG. 4 is a schematic cross sectional view showing a production apparatus according to another modified embodiment of the disclosure.

### DETAILED DESCRIPTION OF PREFERRED EMBODIMENTS

An apparatus according to a first aspect of the disclosure is an apparatus for producing a Group III nitride crystal, contains:

a chamber;

a nitrogen element-containing gas supplying port for supplying a nitrogen element-containing gas to the chamber;

a compound gas supplying port for supplying a compound gas of the Group III element to the chamber, so as to mix the compound gas with the nitrogen element-containing gas;

a discharging port for discharging the compound gas and the nitrogen element-containing gas thus mixed, outside the chamber;

a holder for holding a seed substrate at a position that is on a downstream side of a mixing point of the compound gas and the nitrogen element-containing gas and is an upstream side of the discharging port;

a first heater for heating the seed substrate; and

a second heater for heating a space between the mixing point and the seed substrate to a temperature that is higher than a temperature heated by the first heater.

According to a second aspect of the disclosure, in the apparatus for producing a Group III nitride crystal according to the first aspect,

the apparatus may further contain a ring that surrounds the seed substrate and the holder, and

the second heater may heat the ring.

According to a third aspect of the disclosure, in the apparatus for producing a Group III nitride crystal according to the second aspect, the apparatus may further contain an air layer between the holder and the ring.

A method according to a fourth aspect of the disclosure, in the apparatus for producing a Group III nitride crystal according to any one of the first to third aspects,

the second heater may heat to a temperature, at which a reaction product of the compound gas and the nitrogen element-containing gas is not deposited, and

the first heater may heat to a temperature, at which a reaction product of the compound gas and the nitrogen element-containing gas is deposited.

According to a fifth aspect of the disclosure, in the apparatus for producing a Group III nitride crystal according to any one of the first to fourth aspects, a distance between the mixing point and the seed substrate may be 40 mm or more and 50 mm or less.

According to a sixth aspect of the disclosure, in the apparatus for producing a Group III nitride crystal according to any one of the first to fifth aspects, a difference in temperature between the first heater and the second heater may be 50° C. or more and 100° C. or less.

According to a seventh aspect of the disclosure, a method for producing a Group III nitride crystal, contains a step of producing a Group III nitride crystal by using the apparatus for producing a Group III nitride crystal according to any one of the first to sixth aspects.

According to an eighth aspect of the disclosure, in the method for producing a Group III nitride crystal according to the seventh aspect, the compound gas may be an oxide gas of the Group III element.

According to a ninth aspect of the disclosure, in the method for producing a Group III nitride crystal according to the eighth aspect, the compound gas may be formed through oxidation or reduction of a substance containing the Group III element.

The apparatus for producing a Group III nitride crystal and the method for producing a Group III nitride crystal according to the embodiments of the disclosure will be described in detail below with reference to the drawings. In the drawings, members that have substantially the same function may be referred with reference to the same symbol.

### EMBODIMENT

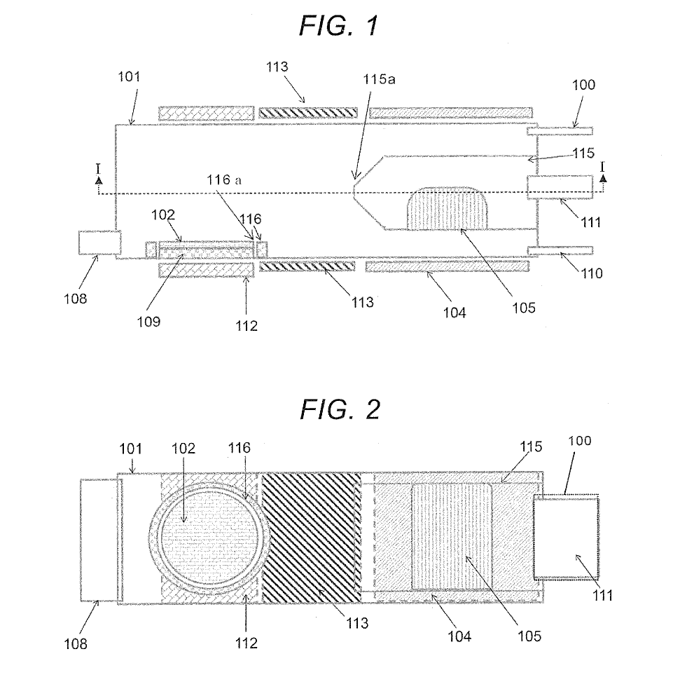

FIG. 1 is a schematic cross sectional view showing a production apparatus of a group III nitride crystal according to an embodiment of the disclosure. In the drawings, the sizes and proportions of the constitutional members may be different from the actual ones for the convenience of understanding. The production apparatus contains a chamber 101, and disposed therein a quartz tube 115 functioning as a supplying port for a reduced product gas of a Group III oxide. The right end of the quartz tube 115 is fixed to the inner wall of the chamber 101, to which a reducing gas is supplied through a reducing gas introducing tube 111. In the quartz tube 115, a Group III oxide raw material stage 105 is disposed. The shape of the Group III oxide raw material is preferably such a shape that has a large contact area to the reducing gas passing thereon for accelerating the reaction. In this embodiment, the Group III oxide raw material used may be, for example, Ga₂O₃ powder a purity of four nines (99.99%) or higher.

Examples of the reducing gas include carbon monoxide gas, a hydrocarbon gas, such as methane gas and ethane gas, hydrogen gas, hydrogen sulfide gas, and sulfur dioxide gas. The reducing gas used in this embodiment is hydrogen gas. The gas is preferably heated and supplied to the chamber 101. The gas may be supplied at ordinary temperature. The flow rate of the gas may be changed depending on the size of the seed substrate 102. A raw material heater 104 is provided around the quartz tube 115, and the reaction of the scheme (I) is performed in the quartz tube 115. According thereto, a reduced product gas of the Group III oxide is supplied from the quartz tube 115 to the chamber 101. Thus, an apical end 115a of the quartz tube 115 functions as a reduced product gas supplying port for supplying the reduced product gas of the Group III oxide to the chamber 101.

In the chamber 101, the seed substrate 102 is disposed on a holder 109. The holder 109 may have a substrate rotation mechanism. The seed substrate 102 may be rotated at a rotation number of from 10 to 100 rpm, and thereby the flatness of the crystal thus formed may be enhanced.

Outside the chamber 101, a substrate heater 112 (first heater) for heating the seed substrate 102 and a substrate upstream side heater 113 (second heater) for heating a space on the upstream side of the seed substrate 102 and a ring 116 disposed to surround the seed substrate 102 and the holder 109 are disposed.

The substrate upstream side heater 113 heats the space in a range of from the apical end 115a and the ring 116. The nitrogen element-containing gas is supplied from the nitrogen element-containing gas supplying port 100 to the chamber 101.

Examples of the nitrogen element-containing gas include ammonia gas, hydrazine gas and an alkylamine gas. Among these, ammonia gas is preferably used in consideration of the safety and the production cost.

The ring 116 is disposed to surround the seed substrate 102 and the holder 109, and has a function of preventing attachments from being deposited to the circumference of the substrate 102 by maintaining a higher temperature of the ring 116 than the seed substrate 102. The holder 109 and the ring 116 may be formed, for example, of such a material as carbon or silicon carbide, which have high thermal conductivity. In particular, the ring 116 is preferably formed of a material that has higher thermal conductivity than the material of the holder 109. Alternatively, the ring 116 is preferably formed of a material having high heat resistance, such as sapphire. The ring 116 may optimally have a ring shape but may be in such a shape that has a discontinuous part, such as a C-shape. In the case where the ring 116 is a member having a C-shape, the discontinuous part thereof is preferably disposed on the downstream side but not the upstream side from the standpoint of the temperature control and the gas flow control.

The ring 116 is disposed to make a gap with respect to the seed substrate 102 and the holder 109. Thus, an air layer 116a is disposed between the holder 109 and the ring 116. The air layer 116a prevents the heat of the ring 116 at a high temperature from migrating to the seed substrate 102 and the holder 109, and thereby the seed substrate 102 may be maintained to the desired temperature. In the case where the holder 109 has a rotation mechanism of the substrate, the air layer 116a prevents the holder 109 and the ring 116 from interfering with each other to achieve smooth rotation of the substrate. The air layer 116a herein preferably has a thickness of 0.5 mm or more and 10 mm or less. In the case where the thickness of the air layer 116a is less than 0.5 mm, smooth rotation of the substrate may not be achieved due to the interference of the holder 109 and the ring 116, and in the case where it exceeds 10 mm, a region having a lower temperature may be formed between the seed substrate 102 and the ring 116 due to the too large distance therebetween, and thus the air layer 116a of the embodiment may fail to exhibit the function thereof.

The reduced product gas of the Group III oxide supplied from the quartz tube 115 and the nitrogen element-containing gas supplied from the nitrogen element-containing gas supplying port 100 are mixed in the chamber 101 and reaches the discharging port 108 positioned at the left end of the chamber 101 through the principal surface of the seed substrate 102. The mixed gas performs the reaction shown by the reaction scheme (II). The holder 109 is employed for holding the seed substrate 102 at a position that is on the downstream side of the mixing point of the reduced product gas of the Group III oxide and the nitrogen element-containing gas and is an upstream side of the discharging port 108.

In the apparatus, the mixing point of the reduced product gas of the Group III oxide and the nitrogen element-containing gas is at the apical end 115a of the quartz tube 115. At the apical end 115a, the reduced product gas of the Group III oxide and the nitrogen element-containing gas are in contact with each other and are mixed.

On the right lower side of the inner wall of the chamber 101, a background gas introducing tube 110 is disposed. Examples of the background gas introduced include an inert gas, such as nitrogen gas, helium gas, argon gas and krypton gas. The background gas is preferably nitrogen gas in consideration of the cost.

Examples of the shape of the chamber 101 include a cylindrical columnar shape, a rectangular columnar shape, a triangular columnar shape, and a shape obtained by combining these shapes. Examples of the material for forming the chamber 101 include quartz, alumina, aluminum titanate, mullite, tungsten and molybdenum. In this embodiment, the shape of the chamber 101 used is a rectangular columnar shape, and the material thereof is quartz.

The quartz tube 115, the nitrogen element-containing gas supplying port 100, the background gas introducing tube 110 and the discharging port 108 may be formed of the same material as the chamber 101. The cross sectional shapes of these tube, supplying port, introducing tube and discharging port are not limited to a circular shape and may be a polygonal shape.

Examples of the raw material heater 104, the substrate heater 112 and the substrate upstream side heater 113 include a resistive heater, such as a ceramic heater and a carbon heater, a high frequency heater, and a light condensing heater. The temperature control thereof may be performed with a controller, such as a computer. The controller has a circuit board, and the circuit board has a processor or a separate device. The processor or the device stores a predetermined program, and a predetermined process is performed by the program.

According to the aforementioned structure of the apparatus, crystals may be prevented from being deposited on the upstream side of the seed substrate 102, and a single crystal with high quality may be grown on the seed substrate 202. The mechanism thereof will be described below.

The amount of a crystal undergoing sublimation reaction, such as a Group III nitride, that can be present in the form of gas at a certain temperature (i.e., the saturation amount) is limited, and the crystal exceeding the saturation amount is solidified on a solid matter in the space where the crystal and the solid matter are present therein. At this time, a single crystal is formed and is the only deposition on the seed substrate 102, but polycrystals or an amorphous matter is deposited on the other members (such as the inner wall of the chamber 101).

In the apparatus of this embodiment, the gas flow path (space) between the mixing point, where the reduced product gas of the Group III oxide and the nitrogen element-containing gas are mixed, and the seed substrate 102 is heated with the substrate upstream side heater 113. At this time, the substrate upstream side heater 113 is controlled to produce a higher temperature than the substrate heater 112. According to the procedure, polycrystals are prevented from being deposited on the other members than the seed substrate 102, and a single crystal is grown only on the seed substrate 102 as the target.

Assuming that the ratio of the current partial pressure of a gas of a certain substance at a certain temperature to the pressure where the substance can be present as a gas at the temperature is designated as a supersaturation degree, the supersaturation degree x1 of the mixed gas at the temperature achieved by the substrate heater 112 satisfies the relationship, 1<x1<1.2, and the supersaturation degree x2 thereof at the temperature achieved by the substrate upstream side heater 113 satisfies the relationship, 0.8<x2<1. The temperatures that satisfy these relationships are used, i.e., the substrate heater 112 heats to a temperature, at which the reaction product of the reduced product gas of the Group III oxide and the nitrogen element-containing gas is deposited, whereas the substrate upstream side heater 113 heats to a temperature, at which the reaction product of the reduced product gas of the Group III oxide and the nitrogen element-containing gas is not deposited. According to the procedure, crystals may be prevented from being deposited on the other member than the seed substrate 102, and a crystal with high quality may be grown only on the seed substrate 102. The temperature, at which the reaction product of the reduced product gas of the Group III oxide and the nitrogen element-containing gas is deposited, is, for example, 1,200° C., and the temperature, at which the reaction product of the reduced product gas of the Group III oxide and the nitrogen element-containing gas is not deposited, is, for example, from 1,260 to 1,300° C.

In this apparatus, for forming a gas flow through suction from the discharging port 108, the pressure inside the chamber 101 may be in a range of from 9.5×10⁴ to 9.9×10⁴ Pa. The inner pressure of the chamber 101 may be thus maintained to a negative pressure (with respect to the atmospheric pressure), and thereby the gas flow may be smoothed to prevent crystals from being deposited on the other members than the seed substrate 102. The inner pressure of the chamber 101 may be controlled to a range of from 1.0×10⁵ to 5.0×10⁵ Pa by reducing the inner diameter of the discharging port 108. The inner pressure of the chamber 101 may be maintained to a positive pressure (with respect to the atmospheric pressure, and thereby the reaction may be accelerated.

FIG. 2 is a schematic cross sectional view showing the apparatus of this embodiment viewed from the above, in which the upper part of the apparatus cut out at the broken line I-I in FIG. 1. The ring 116 is disposed around the seed substrate 102, and the nitrogen element-containing gas supplying port 100 and the apical end of the quartz tube 115 are disposed on the upstream side of the seed substrate 102 and the ring 116. The widths of the nitrogen element-containing gas supplying port 100, the quartz tube 115 and the discharging port 108 may be equivalent to or larger than the diameter of the seed substrate 102.

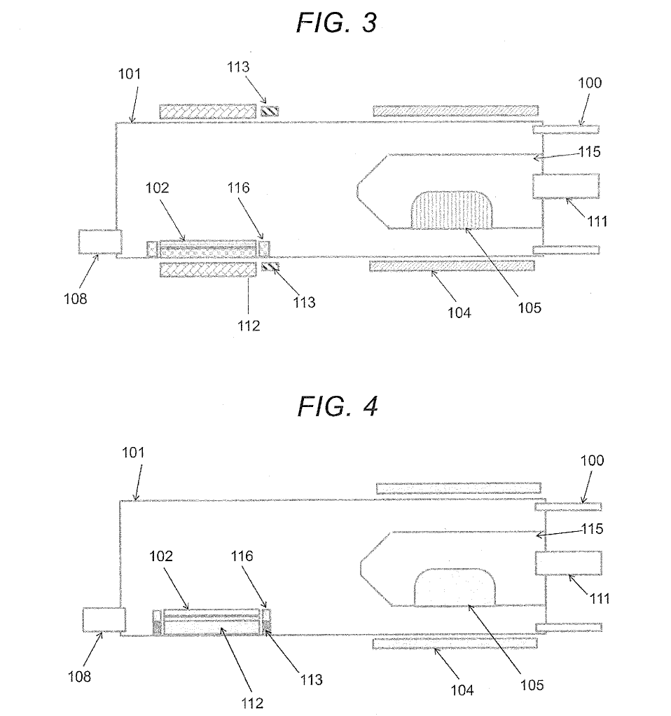

As shown in FIG. 3, the substrate upstream side heater 113 may have such a shape that heats only the ring 116 and the space above the ring 116 in the vertical direction. In the case where the nitrogen element-containing gas and the background gas are those that are less diffusible, the mixing with the reduced product gas of the Group III oxide is somewhat slow to form a flow in the transverse direction after the nitration, and thus crystals are difficult to be deposited on the upstream side of the ring 116. However, the gas flow collides with the ring 116, which is a shielding member perpendicular to the gas flow. For preventing the deposition due to the collision, only the ring 116 and the space above the ring 116 in the vertical direction are heated. According to the structure, a single crystal with high quality may be produced while achieving energy saving.

The diffusibility of gas is influenced by the molecular weight of the component of the gas, and is lowered (difficulty in diffusion) with a smaller molecular weight. Based on such knowledge, nitrogen having a large molecular weight is used in the gas which is less diffusible. Specifically, the nitrogen element-containing gas that is less diffusible may be ammonia gas, and the background gas that is less diffusible may be nitrogen gas.

As shown in FIG. 4, the seed substrate 102 and the ring 116 may be separately heated with a plate heater.

In the case where the temperature on the downstream side of the seed substrate 102 is too low, the residual matters of the gases may be crystallized and deposited on the inner wall of the chamber 101 to deteriorate the maintenance property thereof significantly in some cases. For addressing this, the part of the chamber 101 on the downstream side of the seed substrate 102 may be entirely heated to facilitate the discharge of the residual matters as in the form of gas outside the chamber 101. According to the structure, the lifetime of the apparatus may be prolonged, and the maintenance property thereof may be improved.

In the case of a compound crystal, such as a Group III nitride crystal, a prescribed reaction time is necessary after mixing the reduced product gas of the Group III oxide and the nitrogen element-containing gas until the deposition of a single crystal. If the deposition occurs before the elapse of the prescribed reaction time, polycrystals may be deposited in some cases. Thus, the linear distance between the mixing point of the nitrogen element-containing gas supplied from the nitrogen element-containing gas supplying port 100 and the reduced product gas of the Group III oxide supplied from the quartz tube 115 and the seed substrate 102 may be 40 mm or more and 50 mm or less. The inventors have found that the distance in the range is optimum for ensuring the time and the space for performing the reaction of the mixed gas. In the case where the linear distance is less than 40 mm, the gases may be insufficiently reacted, and the reaction intermediate may be deposited as polycrystals on the seed substrate 102. In the case where the linear distance exceeds 50 mm, the nitrogen element-containing gas may be diffused to make the concentration thereof in the mixed gas small, and a single crystal may not be grown on the entire surface of the seed substrate 102.

The length of the substrate heater 112 (in the gas flow path direction) is preferably (diameter of the seed substrate 102)+1 mm or more and 10 mm or less. In the case where the length of the substrate heater 112 is less than (diameter of the seed substrate 102)+1 mm, the temperature of the edge portion of the seed substrate 102 may not be sufficiently lowered, and thus the gas heated with the substrate upstream side heater 113 may not be sufficiently cooled on the edge portion of the seed substrate 102 thereby causing a failure to deposit the crystal. In the case where the length of the substrate heater 112 exceeds (diameter of the seed substrate 102)+10 mm, the distance between the substrate upstream side heater 113 and the seed substrate 102 may be too large, and thus crystals may be deposited between them.

The difference in temperature between the substrate heater 112 and the substrate upstream side heater 113 is preferably 50° C. or more and 100° C. or less. In the case where the difference in temperature is less than 50° C., the effect of suppressing the deposition of polycrystals may not be exhibited. In the case where the difference in temperature exceeds 10° C., the seed substrate 102 may be warped. In this embodiment, the substrate heater 112 may be set at 1,200° C., and the substrate upstream side heater 113 may be set at from 1,260° C. to 1,300° C., which are measured with a thermocouple disposed around them. The difference in temperature referred herein means the difference in temperature between the part of the seed substrate 102 that has the minimum temperature and the part of the portion heated with the substrate upstream side heater 113 that has the maximum temperature.

The substrate heater 112 and the substrate upstream side heater 113 may be provided to continuously surround the outer wall of the chamber 101. In this case, the heaters may be divided against each other.

The flow path of the mixed gas of the reduced product gas of the Group III oxide and the nitrogen element-containing gas is more preferably provided at a position within 30 mm or less from above the substrate upstream side heater 113. In the case where the gas flow path is provided at a position more than 30 mm above the substrate upstream side heater 113, the radiation heating effect with the substrate upstream side heater 113 may be too weak to cause deposition of polycrystals.

The nitrogen element-containing gas supplying port 100 is preferably positioned above the supplying port of the quartz tube 115. The specific gravity of the reduced product gas of the Group III oxide is larger than the nitrogen element-containing gas, and therefore, in the case where the supplying port of the quartz tube 115 is above the nitrogen element-containing gas supplying port 100, the nitrogen element-containing gas may be prevented from reaching the seed substrate 102.

In the embodiment shown in FIG. 1, the height from the seed substrate 102 to the top wall of the chamber 101, i.e., the height of the crystal growing space, is preferably 30 mm or more and 60 mm or less. In the case where the height of the crystal growing space is less than 30 mm, the formation of polycrystals may be accelerated due to the too narrow space for transporting the gases. In the case where the height of the crystal growing space exceeds 60 mm, on the other hand, the nitrogen element-containing gas may diffuse to make difficult the maintenance of the nitrogen containing gas concentration on the seed substrate 102.

The apparatus of this embodiment may be applied to cases where other Group III oxides than Ga₂O₃ are used. Examples of the other Group III oxides include In₂O₃ for the case where the Group III element is In (indium), Al₂O₃ for the case where the Group III element is Al (aluminum), B₂O₃ for the case where the Group III element is B (boron), and Tl₂O₃ for the case where the Group III element is Tl (thallium).

In this embodiment, the right side of the apparatus is the upstream side, whereas the left side thereof is the downstream side, but the directions may be reversed to each other.

The nitrogen element-containing gas supplying port 100 may be provided to penetrate through the top wall of the chamber 101. In this case, the nitrogen element-containing gas supplying port 100 may be disposed to be slanted toward the downstream side.

The method for producing a Group III oxide crystal may be performed by using the apparatus for producing a Group III nitride crystal. According to the production method, a Group III oxide crystal with high quality may be produced.

Oxides of the Group III element, such as Ga₂O₃, are materials that are stable in the air, and may be advantageously handled easily. Alternatively, a metal of a Group III element, such as Ga, may be prepared instead of an oxide of a Group III element, such as Ga₂O₃, and the compound gas of the Group III element, such as Ga₂O, may be formed by supplying an oxidizing gas to the metal of a Group III element. In this case, the metal of a Group III element may be disposed on the Group III oxide raw material stage 105, and an oxidizing gas may be supplied from the reducing gas introducing tube 111, thereby forming Ga₂O as a compound gas of the Group III element. The quartz tube 115 in this case functions as a compound gas supplying port for supplying the compound gas to the chamber 101, so as to mix with the nitrogen element-containing gas. Examples of the oxidizing gas include oxidizing agents, such as H₂O gas, O₂ gas, CO₂ gas and CO gas. In all the cases where the raw material disposed on the Group III oxide raw material stage 105 is Ga₂O₃ (oxide) and Ga (metal), the same Ga₂O gas (i.e., the oxide gas of the Group III element) may be formed in this embodiment. In this embodiment, the compound gas may be formed by oxidizing or reducing a substance containing a Group III element. According thereto, production method and apparatus with high efficiency may be achieved.

A metal of a Group III element, such as Ga, has such advantages that a high purity material may be generally available at low cost as compared to an oxide of a Group III element. Furthermore, some species of metals of the Group III element, such as Ga, also have such advantages that the metals are in the form of a liquid at a low temperature and thus facilitate the use of a mechanism for continuously supplying the material, and the metals form no H₂O on forming the oxide gas and thus suppresses the quality of the Group III nitride crystal from being deteriorated.

### Example 1

An apparatus for producing a Group III nitride crystal in Example 1 had the structure shown in FIG. 1. In Example 1, the diameter of the seed substrate was 170 mm, the length of the substrate upstream side heater was 45 mm, and the length of the substrate heater was (diameter of the seed substrate)+6 mm. The heating temperature by the substrate heater was 1,200° C., the heating temperature by the substrate upstream side heater was 1,270° C. The mixing point of the reduced product gas of the Group III oxide and the nitrogen element-containing gas was disposed at a height of 15 mm above the substrate upstream side heater. Such a structure was used that the reduced product gas of the Group III oxide and the nitrogen element-containing gas were blown horizontally. The height of the crystal growing space was 45 mm. In Example 1, Ga₂O as the raw material gas was supplied at 0.05 L/m, hydrogen as the reducing gas was supplied at 10 L/m, ammonia as the nitrogen element-containing gas was supplied at 5 L/m, and the rotation number of the seed substrate was 10 rpm.

### Example 2

A crystal was grown under the same conditions as in Example 1 except that the length of the substrate upstream side heater was the same as the length of the ring 116.

### Example 3

A crystal was grown under the same conditions as in Example 1 except that the length of the substrate upstream side heater was 40 mm.

### Example 4

A crystal was grown under the same conditions as in Example 1 except that the heating temperature by the substrate heater was 1,200° C., and the heating temperature by the substrate upstream side heater was 1,300° C.

### Example 5

A crystal was grown under the same conditions as in Example 1 except that the mixing point was disposed at a height of 30 mm above the substrate upstream side heater.

### Comparative Example 1

A crystal was grown under the same conditions as in Example 1 except that the substrate upstream side heater was not used.

### Comparative Example 2

A crystal was grown under the same conditions as in Example 1 except that the difference in temperature was 30° C. in the case where the heating temperature by the substrate heater was 1,200° C., and the heating temperature by the periphery heater was 1,230° C.

### Comparative Example 3

A crystal was grown under the same conditions as in Example 1 except that the distance between the mixing point and the substrate was 30 mm.

### Comparative Example 4

A crystal was grown under the same conditions as in Example 1 except that the distance between the mixing point and the substrate was 60 mm.

Ten crystals were grown for each conditions and evaluated. The crystals were evaluated by the half value width of the X-ray rocking curve. Specifically, a crystal that had a half value width of the X-ray rocking curve of 100 seconds or less was designated as a single crystal with high quality, and the ratio of samples with high quality in the single crystals grown under each conditions was designated as a single crystal rate. The condition providing a single crystal rate of 80% or more was designated as a good condition. The single crystal rates of Examples and Comparative Examples are shown in Table 1. It was confirmed that single crystals with high quality were grown in all Examples. In addition, all Examples exhibited better quality than all Comparative Examples.

TABLE 1

| Sample | Single crystal rate (%) |
|---|---|
| Example 1 | 100 |
| Example 2 | 90 |
| Example 3 | 90 |
| Example 4 | 80 |
| Example 5 | 90 |
| Comparative Example 1 | 20 |
| Comparative Example 2 | 40 |
| Comparative Example 3 | 40 |
| Comparative Example 4 | 70 |

### INDUSTRIAL APPLICABILITY

As described in the foregoing, a crystal with high quality capable of being applied to, for example, a power semiconductor, a heterojunction high speed electron device, and a photoelectric device, such as an LED and a field of laser, may be obtained according to the embodiments.

What is claimed is:

1. An apparatus for producing a Group III nitride crystal, comprising:
a chamber;
a nitrogen element-containing gas supplying port configured to supply a nitrogen element-containing gas to the chamber;
a compound gas supplying port configured to supply a compound gas of a Group III element to the chamber and mix the compound gas with the nitrogen element-containing gas;
a discharging port configured to discharge the compound gas mixed with the nitrogen element-containing gas outside of the chamber;
a holder configured to hold a seed substrate at a position that is on a downstream side of a mixing point of the compound gas and the nitrogen element-containing gas and is an upstream side of the discharging port;
a first heater configured to heat the seed substrate; and
a second heater configured to heat a space between the mixing point and the seed substrate to a temperature that is higher than a temperature heated by the first heater.

2. The apparatus for producing a Group III nitride crystal according to claim 1, wherein
the apparatus further comprises a ring that surrounds the seed substrate and the holder, and
the second heater heats the ring.

3. The apparatus for producing a Group III nitride crystal according to claim 2, wherein the apparatus further comprises an air layer between the holder and the ring.

4. The apparatus for producing a Group III nitride crystal according to claim 1, wherein
the second heater heats to a temperature at which a reaction product of the compound gas and the nitrogen element-containing gas is not deposited, and
the first heater heats to a temperature at which a reaction product of the compound gas and the nitrogen element-containing gas is deposited.

5. The apparatus for producing a Group III nitride crystal according to claim 1, wherein a distance between the mixing point and the seed substrate is at least 40 mm and no greater than 50 mm.

6. The apparatus for producing a Group II nitride crystal according to claim 1, wherein a difference in temperature between the first heater and the second heater is at least 50° C. and no greater than 100° C.

7. A method for producing a Group III nitride crystal, comprising producing a Group III nitride crystal by using the apparatus for producing a Group III nitride crystal according to claim 1.

8. The method for producing a Group III nitride crystal according to claim 7, wherein the compound gas is an oxide gas of the Group III element.

9. The method for producing a Group III nitride crystal according to claim 8, wherein the compound gas is formed through oxidation or reduction of a substance containing the Group III element.

10. An apparatus for producing a Group III nitride crystal, comprising:
a chamber into which a nitrogen element-containing gas and a compound gas of a Group III element are introduced and mixed at a predetermined mixing point along a gas flow path;
a holder configured to hold a seed substrate at a position which is downstream from the predetermined mixing point along the gas flow path;
a first heater configured to heat the seed substrate; and
a second heater configured to heat a space within the chamber located between the predetermined mixing point and the seed substrate to a temperature that is higher than a temperature heated by the first heater.

11. The apparatus for producing a Group III nitride crystal according to claim 10, wherein a difference in temperature between the first heater and the second heater is at least 50° C. and no greater than 100° C.

12. The apparatus for producing a Group III nitride crystal according to claim 11, wherein a distance between the predetermined mixing point and the seed substrate is at least 40 mm and no greater than 50 mm.

13. The apparatus for producing a Group III nitride crystal according to claim 12, wherein
the apparatus further comprises a ring that surrounds the seed substrate and the holder, and
the second heater heats the ring.

14. The apparatus for producing a Group III nitride crystal according to claim 13, wherein the apparatus further comprises an air layer between the holder and the ring.
